(19) United States
(12) Patent Application Publication
(10) Pub. No.: US 2016/0218708 A1
(43) Pub. Date: Jul. 28, 2016

(54) GATE DRIVE APPARATUS

(71) Applicant: Panasonic Intellectual Property Management Co., Ltd., Osaka (JP)

(72) Inventor: NOBORU NEGORO, Osaka (JP)

(21) Appl. No.: 15/089,430

(22) Filed: Apr. 1, 2016

Related U.S. Application Data
(63) Continuation of application No. PCT/JP2014/004322, filed on Aug. 22, 2014.

(30) Foreign Application Priority Data
Oct. 25, 2013 (JP) 2013-221933

(51) Int. Cl. H03K 17/687; H01L 27/06; H01L 29/778; H01L 29/872; H01L 29/20; H01L 29/205

(52) U.S. Cl. CPC H03K 17/687; H01L 29/2003; H01L 29/205; H01L 29/7787; H01L 29/872; H01L 27/0605; H01L 27/0629

(57) ABSTRACT

A gate drive apparatus with an improved gate drive capability to control a switching device includes a signal transmitter, a signal receiver, and an electromagnetic resonance coupler. The signal transmitter includes a gate control signal generator, an oscillator circuit, and a mixer circuit. The signal receiver includes a positive voltage outputting rectifier circuit, a negative voltage outputting rectifier circuit, and a pull-down resistor. The positive voltage outputting rectifier circuit has a positive voltage outputting diode, a first inductor, and a first capacitor. The negative voltage outputting rectifier circuit has a negative voltage outputting diode, a second inductor, and a second capacitor. In the signal receiver, the diode of each rectifier circuit has an anode electrode made of a metal having a low work function. This configuration improves an output voltage amplitude of the gate drive apparatus.

### BACKGROUND OF THE INVENTION

1. Field of the Invention

An exemplary embodiment of the present disclosure relates to a gate drive apparatus for controlling a switching device.

2. Description of the Related Art

A gate drive apparatus for a switching device (i.e., a circuit that drives a semiconductor device) refers to a circuit configured to apply a gate voltage to a gate terminal of a high-voltage switching device, such as an insulated gate bipolar transistor (IGBT), called a power semiconductor device and to turn the power semiconductor switching device on or off.

The reference voltage of the power semiconductor device, that is, the reference potential on the output side of the gate drive circuit rises considerably. Therefore, the gate drive apparatus is required to isolate a direct-current component between the primary side, which is a control signal input part, of a gate drive circuit that drives the switching device and the output side (secondary side) of the gate drive circuit. Particularly, the power semiconductor switching device is driven using an external insulated power supply which considerably upsizes a gate drive system. Hence, if the gate drive apparatus is configured to isolate a gate signal and to supply isolated electric power to the gate, the gate drive system requires no external insulated power supply. As a result, the gate drive system is downsized.

Examples of a circuit configuration for achieving the signal isolating function described above may include a configuration that a gate signal is isolated using a wireless signal transmitter such as an electromagnetic resonance coupler (see, for example, NPTL 1).

A voltage amplitude of at least about a dozen or so volts is required for driving a power semiconductor switching device typified by an IGBT; therefore, large electric power is desirably transferred to a reception side.

Attention has been focused on a nitride semiconductor typified by GaN. GaN and AlN respectively have wide bandgaps of 3.4 eV and 6.2 eV at room temperature. Therefore, GaN and AlN each have a large dielectric breakdown field. With regard to an AlGaN/GaN heterostructure, furthermore, spontaneous polarization and piezoelectric polarization on a (0001) plane generate electrical charges on a heterointerface. As a result, a high sheet carrier concentration of not less than 1×10¹³ cm⁻² is obtained even in an undoped state. Thus, a diode and a hetero-junction field effect transistor (HFET) can be realized using two-dimensional electron gas at the heterointerface.

However, if a rectifying diode of the signal receiver in the gate drive apparatus has a high threshold voltage, the gate drive apparatus fails to satisfactorily drive the switching device because of a small output voltage amplitude.

### CITATION LIST

### Non-Patent Literature

NPTL 1: S. Nagai, et al.: “A DC-Isolated Gate Drive IC with Drive-by-Microwave Technology for Power Switching Devices”, Solid-State Circuits Conference Digest of Technical Papers (ISSCC), pp. 404-406 2012.

### SUMMARY OF THE INVENTION

In view of the circumstances described above, an object of the present disclosure is to provide a gate drive apparatus, particularly, an insulated gate drive apparatus that increases an output voltage amplitude by decreasing a threshold voltage of a rectifying diode.

In order to attain the object, an exemplary embodiment of the present disclosure provides a gate drive apparatus including a transmitter, a receiver, and a coupler disposed between the transmitter and the receiver. The transmitter includes an oscillator having a diode. The receiver includes a rectifier circuit having a diode. The diode of the transmitter is different in anode electrode from the diode of the receiver.

With this configuration, the diode of the receiver is made different in threshold voltage from the diode of the transmitter, so that a characteristic of the receiver is improved.

In the gate drive apparatus according to the exemplary embodiment of the present disclosure, the anode electrode of the diode in the transmitter is higher in work function than the anode electrode of the diode in the receiver. With this configuration, a reduction in threshold voltage of the diode in the receiver leads to a reduction in on resistance of the receiver and also leads to an increase in output voltage amplitude of the receiver. In other words, this configuration improves a gate drive capability.

An exemplary embodiment of the present disclosure also provides a gate drive apparatus including a transmitter, a receiver, and a coupler disposed between the transmitter and the receiver. The receiver includes a first rectifier circuit having a first diode, and a second rectifier circuit having a second diode. The first diode is different in anode electrode from the second diode.

With this configuration, the second diode is made different in threshold voltage from the first diode, so that a characteristic of each rectifier circuit is improved.

In the gate drive apparatus according to the exemplary embodiment of the present disclosure, the receiver includes a first rectifier circuit configured to output a positive voltage, and a second rectifier circuit configured to output a negative voltage.

In the gate drive apparatus according to the exemplary embodiment of the present disclosure, an anode electrode of the first diode is higher in work function than an anode electrode of the second diode. With this configuration, a reduction in threshold voltage of the second rectifying diode leads to a reduction in on resistance of the second rectifier circuit and also leads to an increase in output voltage amplitude of the second rectifier circuit. In other words, this configuration improves a gate drive capability.

In the gate drive apparatus according to the exemplary embodiment of the present disclosure, the transmitter includes an oscillator, a gate control signal generator, and a mixer. The oscillator generates a carrier signal. The gate control signal generator generates a gate control signal. The mixer superimposes the carrier signal on the gate control signal to generate a superimposed signal, and generates a positive voltage output signal and a negative voltage output signal.

In the gate drive apparatus according to the exemplary embodiment of the present disclosure, each of the diodes includes a substrate, a buffer layer, a carrier supply layer, a barrier layer, a cathode electrode, and an anode electrode. The buffer layer, the carrier supply layer, and the barrier layer are sequentially disposed on the substrate and are made of a group III nitride semiconductor. The cathode electrode and the anode electrode are disposed on the carrier supply layer or the barrier layer.

In the gate drive apparatus according to the exemplary embodiment of the present disclosure, the diode of the rectifier circuit has, as a part of the anode electrode, a recess formed to pass through the barrier layer and reach the carrier supply layer. This configuration leads to a reduction in capacitance of the diode in the rectifier circuit and also leads to an improvement in switching speed of the rectifying diode.

In the gate drive apparatus according to the exemplary embodiment of the present disclosure, the oscillator includes a transistor. The transistor includes a substrate, a semiconductor layer, a source electrode, a drain electrode, and a gate electrode. The semiconductor layer is disposed on the substrate and includes a buffer layer, a carrier supply layer, and a barrier layer each made of a nitride semiconductor. The source electrode, the drain electrode, and the gate electrode are disposed on the semiconductor layer.

In the gate drive apparatus according to the exemplary embodiment of the present disclosure, a reduction in on resistance and capacitance of the diode leads to an increase of an output voltage amplitude. Thus, an exemplary embodiment of the present disclosure provides a gate drive apparatus with an improved ability to drive a switching device.

### BRIEF DESCRIPTION OF DRAWINGS

FIG. 1 illustrates a configuration of a gate drive apparatus according to an exemplary embodiment of the present disclosure;

FIG. 2 is a sectional view of a transistor according to the exemplary embodiment of the present disclosure;

FIG. 3 is a sectional view of a diode according to the exemplary embodiment of the present disclosure;

FIGS. 4A to 4F are sectional views of the transistor and diode formed in accordance with a process flow;

FIG. 5 illustrates a current-voltage characteristic of the diode;

FIG. 6 illustrates a result of evaluation on an output voltage characteristic of the gate drive apparatus;

FIG. 7 illustrates a configuration of a first modification example of the gate drive apparatus according to the exemplary embodiment of the present disclosure;

FIG. 8A is a sectional view of structure A of the diode in a second modification example of the gate drive apparatus according to the exemplary embodiment of the present disclosure;

FIG. 8B is a sectional view of structure B of the diode in the second modification example of the gate drive apparatus according to the exemplary embodiment of the present disclosure; and

FIG. 9 illustrates a capacitance-voltage characteristic of the diode in the second modification example.

### DETAILED DESCRIPTION OF THE PREFERRED EMBODIMENTS

An exemplary embodiment of the present disclosure will be described below with reference to the accompanying drawings.

### Exemplary Embodiment

### (1) Circuit Configuration of Gate Drive Apparatus

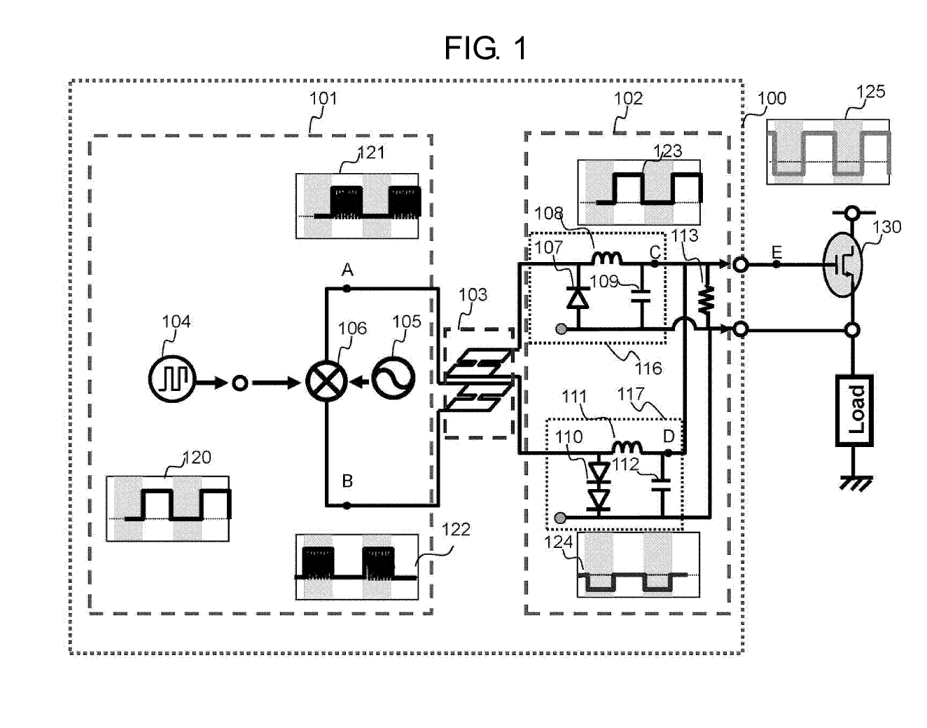

FIG. 1 is a block diagram of a gate drive apparatus according to the exemplary embodiment of the present disclosure. Gate drive apparatus 100 includes signal transmitter 101 (primary side), signal receiver 102 (secondary side), and electromagnetic resonance coupler 103. In gate drive apparatus 100, an anode electrode of a rectifying diode in signal receiver 102 is made of a metal lower in work function than a metal for a gate electrode of a transistor or an anode electrode of a diode in signal transmitter 101.

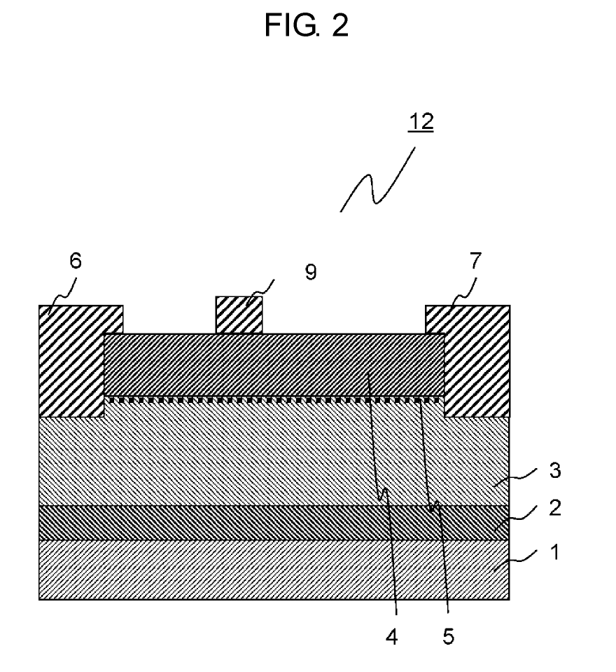

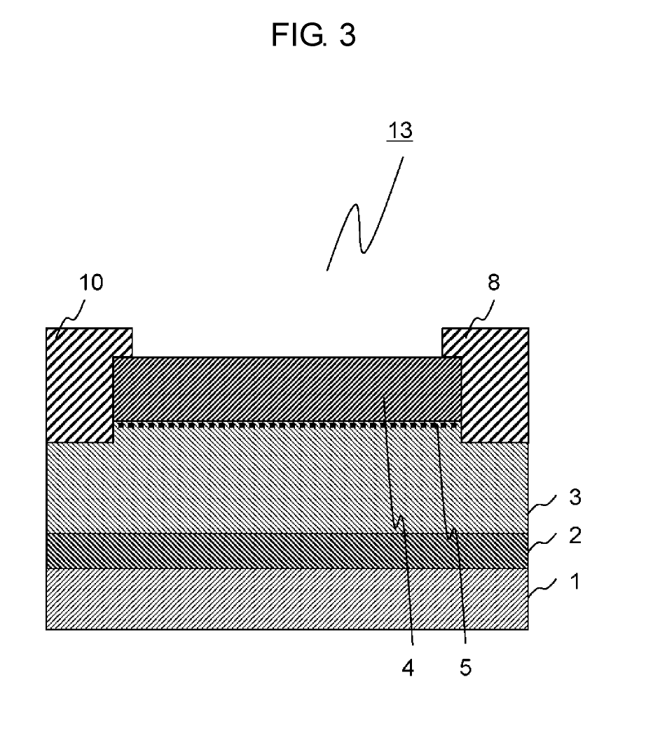

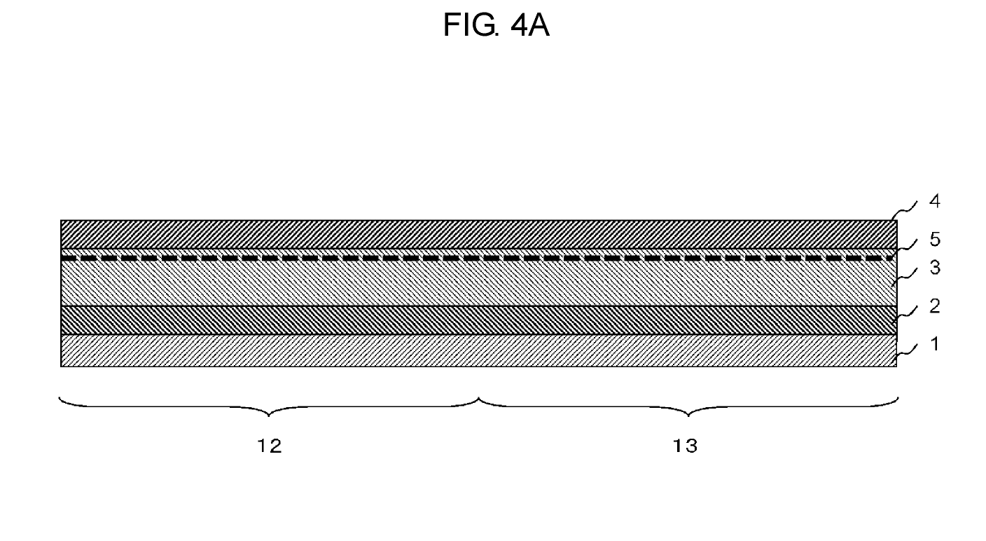

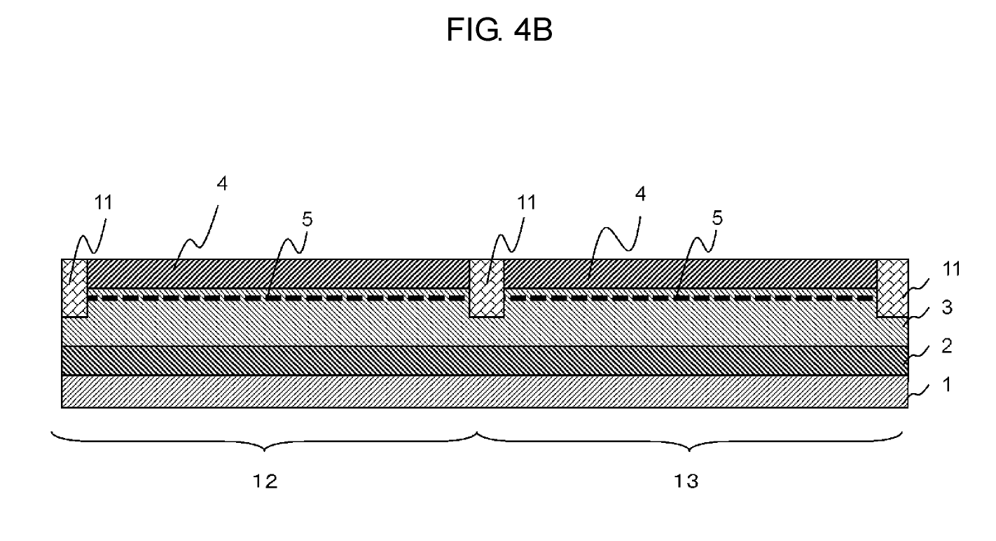

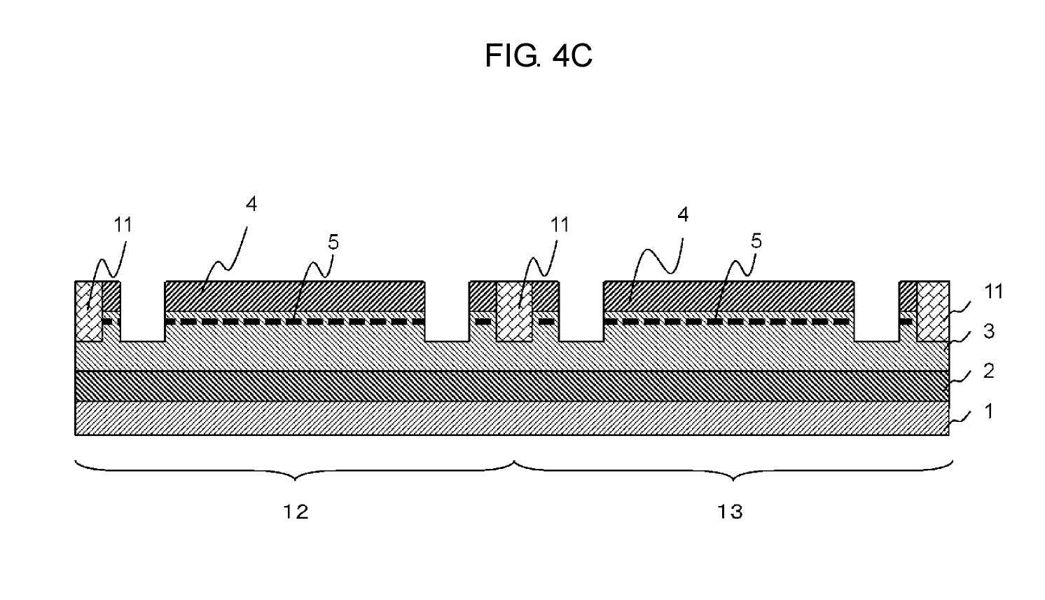

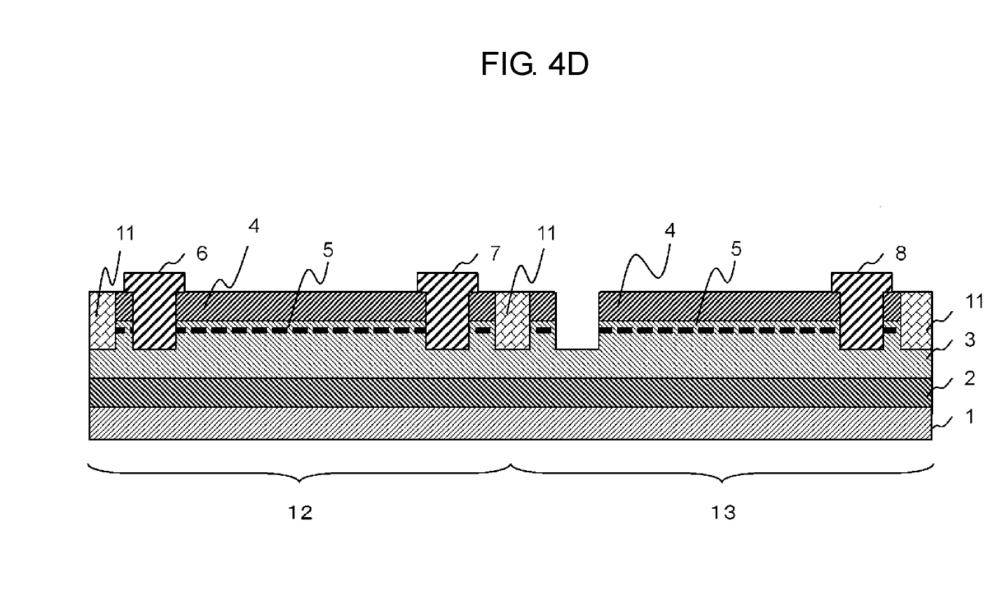

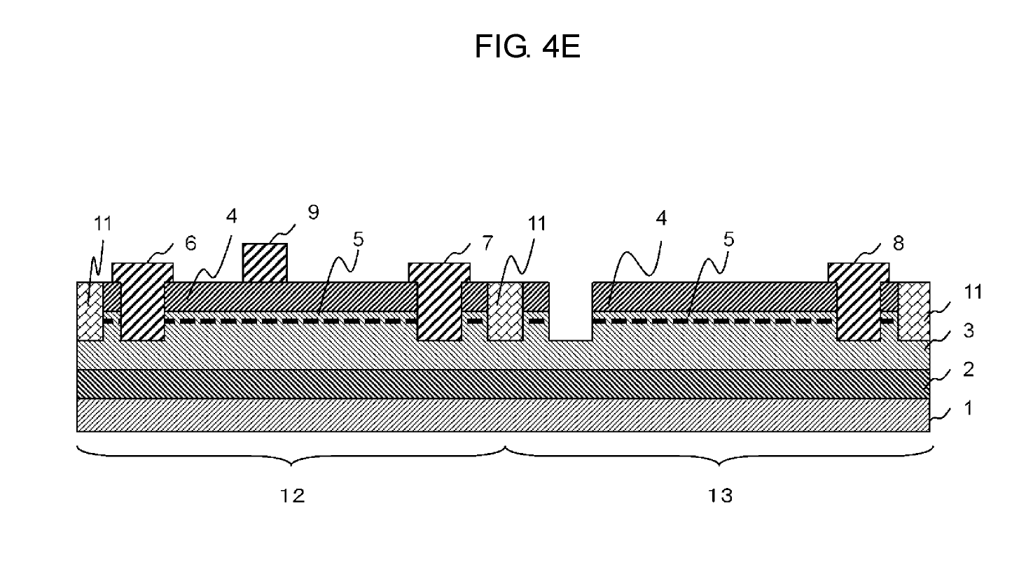

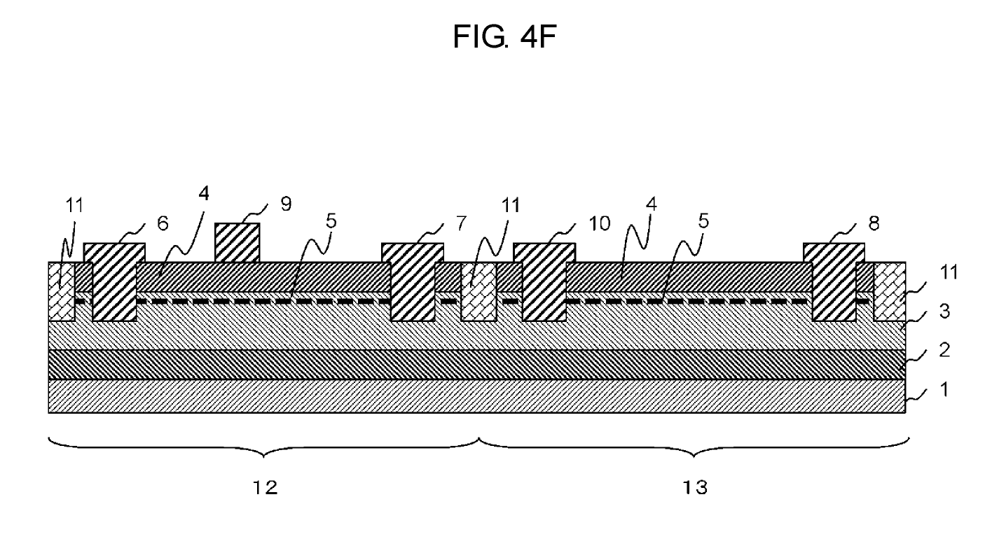

Signal transmitter 101 (primary side) includes gate control signal generator 104, oscillator circuit 105, and mixer circuit 106. Oscillator circuit 105 and mixer circuit 106 are mounted on a single circuit board made of a nitride semiconductor. With regard to the transistors and diodes in signal transmitter 101 excluding gate control signal generator 104 and signal receiver 102, sections and a process flow are respectively illustrated in FIG. 2, FIG. 3, and FIGS. 4A to 4F as will be described in detail later. FIG. 1 also illustrates signal waveforms in the respective circuits (a waveform of PWM signal 120, a waveform of superimposed signal 121 at point A, a waveform of superimposed signal 122 at point B, a waveform of rectified signal 123 at point C, a waveform of rectified signal 124 at point D, and a waveform of gate control signal 125 at point E).

Gate control signal generator 104 generates, as PWM signal 120, a pulse signal in a low frequency of about 10 kHz.

Oscillator circuit 105 includes a transistor, an inductor, a parallel plate capacitor, and a variable capacitance diode for adjusting an oscillation frequency. Oscillator circuit 105 generates a carrier signal of about 2 GHz to 6 GHz. A preferable diode for use in an oscillator has a large change in capacitance for extending a frequency adjustable range. For this reason, the diode may have a recess formed in a part of a barrier layer by etching, rather than a recess passing through the barrier layer. Alternatively, the diode may have no recess. This configuration brings about a large change in capacitance to extend a frequency variable range. Moreover, the oscillation frequency may be adjusted by trimming of the parallel plate capacitor.

Mixer circuit 106 includes a transistor, an inductor, and a parallel plate capacitor. Mixer circuit 106 superimposes PWM signal 120 on the carrier signal, and supplies the signal and electric power to electromagnetic resonance coupler 103. For high speed operation, a switching device is required to be turned on quickly, and is also required to be turned off quickly. For the requirements, gate drive apparatus 100 is configured to output the signal obtained by superimposing PWM signal 120 on the carrier signal by way of two paths, that is, a positive voltage output path (with the waveform of superimposed signal 121 at point A) and a negative voltage output path (with the waveform of superimposed signal 122 at point B). With this configuration, gate drive apparatus 100 applies a negative voltage to a gate terminal of the switching device turned off, to promptly pull electrical charges out of the gate terminal.

Electromagnetic resonance coupler 103 serves to transfer the superimposed signal and electric power from the transmission side to the reception side.

Signal receiver 102 includes positive voltage outputting rectifier circuit 116, negative voltage outputting rectifier circuit 117, and pull-down resistor 113. Positive voltage outputting rectifier circuit 116 includes positive voltage outputting diode 107, first inductor 108, and first capacitor 109. Negative voltage outputting rectifier circuit 117 includes negative voltage outputting diodes 110, second inductor 111, and second capacitor 112.

Pull-down resistor 113 serves to stabilize an output-side impedance of the rectifier circuit even when any load is connected to the output terminal of gate drive apparatus 100, which brings about favorable output. Gate drive apparatus 100 is operable without pull-down resistor 113.

Signal receiver 102 receives a signal obtained by superimposing the superimposed signal 121 at point A on superimposed signal 122 at point B. Then signal receiver 102 distributes the received signal to the two paths of positive voltage outputting rectifier circuit 116 and negative voltage outputting rectifier circuit 117. The signal in positive voltage outputting rectifier circuit 116 corresponds to rectified signal 123 at point C. The signal in negative voltage outputting rectifier circuit 117 corresponds to rectified signal 124 at point D. The signal obtained by superimposing rectified signal 123 at point C on rectified signal 124 at point D corresponds to gate control signal 125.

Gate control signal 125 to be transmitted to switching device 130 is of large amplitude on the positive voltage side and small amplitude on the negative voltage as shown with the waveform at point E in FIG. 1. A negative voltage to be output may be about several volts since the negative voltage is used for pulling gate charges out of the switching device.

In negative voltage outputting rectifier circuit 117, negative voltage outputting diodes 110 are connected in serial so as not to be turned on when a high positive voltage output signal is output.

### (2) Configurations of Transistor and Diode

Next, description will be given of the transistor and the diode according to the exemplary embodiment of the present disclosure.

FIG. 2 is the sectional view of the transistor according to the exemplary embodiment of the present disclosure. FIG. 3 is the sectional view of the Schottky diode according to the exemplary embodiment of the present disclosure.

As illustrated in FIG. 2, transistor 12 according to the exemplary embodiment of the present disclosure includes substrate 1 made of Si and having a main surface of a (111) surface orientation. Transistor 12 also includes a laminated body of buffer layer 2 made of a nitride semiconductor, 1 μm-thick carrier supply layer 3 made of undoped GaN, and 25 nm-thick barrier layer 4 made of undoped Al_{0.3}Ga_{0.7}N. The laminated body is formed on substrate 1. Transistor 12 also includes gate electrode 9 formed on barrier layer 4. Barrier layer 4 is partly removed at two positions until carrier supply layer 3 is exposed from each position. Transistor 12 also includes source electrode 6 formed on carrier supply layer 3 in one of the two positions and drain electrode 7 formed on carrier supply layer 3 in the other position.

As illustrated in FIG. 3, diode 13 according to the exemplary embodiment of the present disclosure includes substrate 1 made of Si and having the main surface of the (111) surface orientation. Diode 13 also includes the laminated body of buffer layer 2 made of the nitride semiconductor, 1 μm-thick carrier supply layer 3 made of undoped GaN, and 25 nm-thick barrier layer 4 made of undoped Al_{0.3}Ga_{0.7}N. The laminated body is formed on substrate 1. Barrier layer 4 is partly removed at two positions until carrier supply layer 3 is exposed from each position. Diode 13 also includes cathode electrode 8 formed on carrier supply layer 3 in one of the two positions, and anode electrode 10 formed on carrier supply layer 3 in the other position.

The term “undoped” herein means that no impurities are introduced intentionally (the same thing may hold true for the following description as to the definition of the term “undoped”). Buffer layer 2, carrier supply layer 3, and barrier layer 4 each have a main surface of a (0001) surface orientation.

Two-dimensional electron gas (2 DEG) layer 5 is formed in the vicinity of an interface between carrier supply layer 3 and barrier layer 4 (on the side of carrier supply layer 3). A 1 nm-thick spacer layer made of AlN may be interposed between carrier supply layer 3 and barrier layer 4 for improving the carrier mobility of 2 DEG.

### (3) Process Flow of Forming Transistor and Diode

With reference to FIGS. 4A to 4F, description will be given of the process flow of forming the transistor and diode according to the exemplary embodiment of the present disclosure.

As illustrated in FIG. 4A, first, buffer layer 2 made of the nitride semiconductor, 1 μm-thick carrier supply layer 3 made of undoped GaN, and 25 nm-thick barrier layer 4 made of undoped Al_{0.3}Ga_{0.7}N are sequentially formed on substrate 1 made of Si and having the main surface of the (111) surface orientation.

2 DEG layer 5 is formed in the vicinity of the interface between carrier supply layer 3 and barrier layer 4 (on the side of carrier supply layer 3).

As illustrated in FIG. 4B, device isolation regions 11 are formed in such a manner that ions such as argon are implanted in predetermined positions of barrier layer 4 so as to reach carrier supply layer 3.

As illustrated in FIG. 4C, recesses are formed in such a manner that barrier layer 4 is subjected to etching at predetermined positions until the recesses reach carrier supply layer 3.

As illustrated in FIG. 4D, in transistor 12, source electrode 6 and drain electrode 7 each including a multilayer film of Ti and Al are formed to cover the corresponding recesses. Moreover, in diode 13, cathode electrode 8 is formed to cover the recess formed in the cathode region. In this exemplary embodiment, each of source electrode 6, drain electrode 7, and cathode electrode 8 is subjected to appropriate annealing so as to be in ohmic contact with 2 DEG layer 5. The recesses are not necessarily formed so as to pass through barrier layer 4. Alternatively, the recesses are not necessarily provided.

As illustrated in FIG. 4E, in transistor 12, gate electrode 9 including a multilayer film of Ni and Au is formed on barrier layer 4 and between source electrode 6 and drain electrode 7. As illustrated in FIG. 4F, with regard to the diode of each rectifier circuit in signal receiver 102, on the other hand, anode electrode 10 including a multilayer film of Ti and Au is formed to cover the recess formed in the anode region. The diode of oscillator circuit 105 in signal transmitter 101 has an anode electrode including a multilayer film of Ni and Au. In this exemplary embodiment, each of gate electrode 9 and anode electrode 10 is in Schottky contact with a semiconductor. As to a work function of a metal that establishes a Schottky barrier junction, Ni for the transistor is about 5.2 eV and Ti for the diode is about 4.2 eV. Typically, a Schottky barrier height to an electron is determined from the electron affinity of a semiconductor and the work function of a metal. If a metal to be used has a high work function, the Schottky barrier height increases and a forward bias until electric current flows (i.e., a Schottky electrode is applied with a positive voltage and an ohmic electrode is grounded) also increases. The transistor is made of a metal having a high work function as described in this exemplary embodiment since a gate current flowing through the transistor at the time of forward bias is not preferred for the transistor. On the other hand, the diode is made of Ti having a low work function since a low threshold voltage allows an improvement in on resistance and therefore allows a reduction in loss.

### (4) Diode of Rectifier Circuit

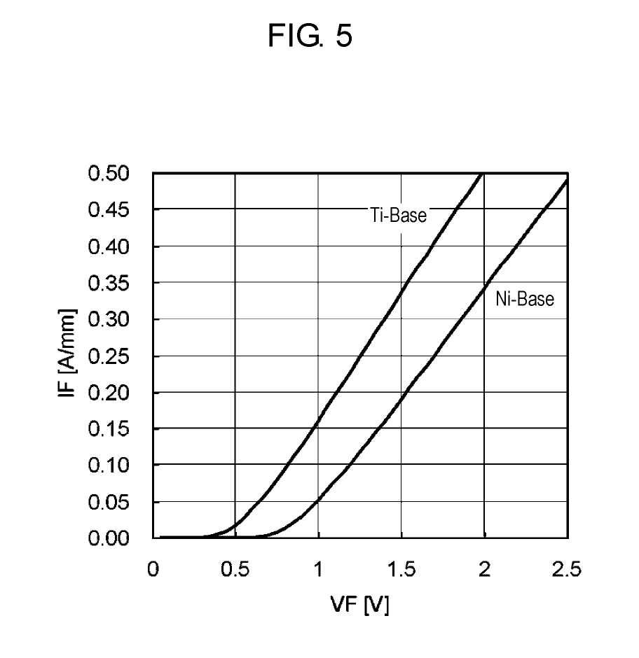

A diode of a rectifier circuit has a lower loss and a more favorable rectifying characteristic as the on resistance is lower. The on resistance of the diode is lowered in such a manner that the channel resistance of the diode is lowered or the contact resistance of an ohmic electrode is lowered. Alternatively, the threshold voltage of the diode is reduced. However, the channel resistance is based on an epitaxial layer structure (a multilayer structure of layers that form a transistor) and the contact resistance is optimized. Therefore, both the channel resistance and the contact resistance cannot be reduced with ease. For this reason, the inventors have studied to reduce a threshold voltage of a diode in a rectifier circuit. Specifically, an anode electrode of a diode in a transistor or oscillator was made of Ni having a high work function and Ti having a low work function, and an evaluation was made on the forward characteristic of the diode. FIG. 5 illustrates results of the evaluation. The diode having the anode electrode made of Ti was superior to the diode having the anode electrode made of Ni in that the threshold voltage was reduced by about 0.4 V. In the comparison using the same voltage, the forward current was increased by not less than 0.1 A/mm and the on resistance was improved. The similar advantageous effects were found from results of two-terminal measurement made on the transistor having the electrodes described above. Table 1 shows a threshold voltage and a Schottky barrier height each obtained from the evaluation on the forward characteristic. As can be seen from Table 1, the use of Ti having a low work function decreases the Schottky barrier height, which leads to a reduction of the threshold voltage.

TABLE 1

| | |
|---|---|
| Transistor | Diode |

| Electrode | Vth [V] | ΦB [eV] | Vth [V] | ΦB [eV] |
|---|---|---|---|---|
| Ni | 0.85 | 0.7 | 0.85 | 0.7 |
| Ti | 0.4 | 0.4 | 0.4 | 0.5 |

In Table 1, Vth represents the threshold voltage (unit: V), and (DB represents the Schottky barrier height (unit: eV).

### (5) Evaluation on Gate Drive Apparatus

Next, gate drive apparatuses were prepared, which include anode electrodes having different work functions. Specifically, the following four gate drive apparatuses were prepared. In apparatus A, diode 107 of positive voltage outputting rectifier circuit 116 and diodes 110 of negative voltage outputting rectifier circuit 117 respectively have an anode electrode made of Ni. In apparatus B, diode 107 of positive voltage outputting rectifier circuit 116 has an anode electrode made of Ni and diodes 110 of negative voltage outputting rectifier circuit 117 respectively have an anode electrode made of Ti. In apparatus C, diode 107 of positive voltage outputting rectifier circuit 116 has an anode electrode made of Ti and diodes 110 of negative voltage outputting rectifier circuit 117 respectively have an anode electrode made of Ni. In apparatus D, diode 107 of positive voltage outputting rectifier 116 and diodes 110 of negative voltage outputting rectifier circuit 117 respectively have an anode electrode made of Ti.

Next, description will be given of characteristics of apparatuses A to D. Table 2 shows results of evaluation on an output voltage amplitude with regard to apparatuses A to D. In Table 2, a term “positive voltage” represents the positive voltage outputting rectifier circuit, and a term “negative voltage” represents the negative voltage outputting rectifier circuit.

TABLE 2

Value of voltage amplitude (V)

| Apparatus | Positive voltage | Negative voltage |
|---|---|---|
| Apparatus A | 0.85 | 0.1 |
| Apparatus B | 0.85 | 0.5 |
| Apparatus C | 1.19 | 0.1 |
| Apparatus D | 1.19 | 0.5 |

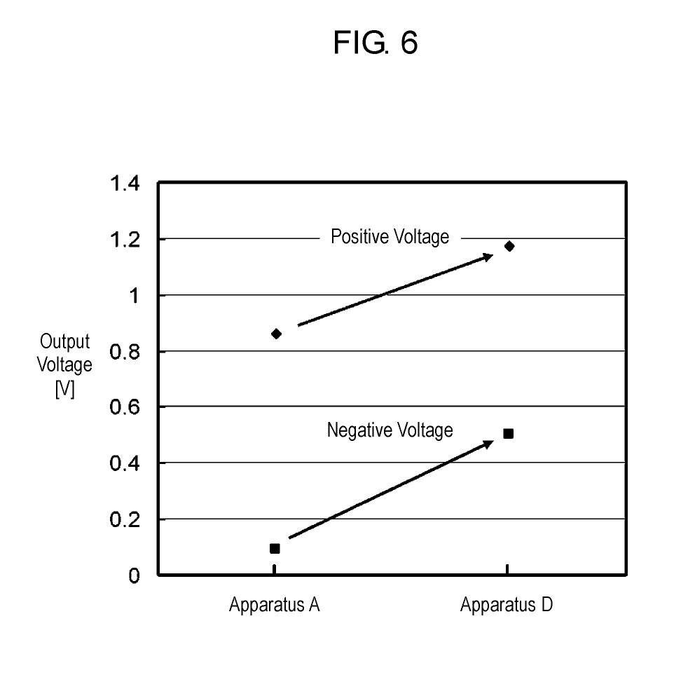

FIG. 6 illustrates results of evaluation and comparison on output voltage characteristics of apparatuses A and D each of which corresponds to the gate drive apparatus according to the exemplary embodiment of the present disclosure. In FIG. 6, a term “positive voltage” represents the output voltage amplitude of the positive voltage outputting rectifier circuit whereas a term “negative voltage” represents the output voltage amplitude of the negative voltage outputting rectifier circuit. A carrier signal to be generated by oscillator circuit 105 has an oscillation frequency set to 2.9 GHz. FIG. 6 illustrates the results in the case of using the signal having the oscillation frequency of 2.9 GHz.

As can be seen from the results in Table 2 and FIG. 6, apparatus D is superior to apparatus A in that the output voltage amplitude is increased by 0.34 V in the positive voltage outputting rectifier circuit and the output voltage amplitude is increased by 0.4 V in the negative voltage outputting rectifier circuit. In other words, Ti-based anode electrode is larger in output voltage amplitude than Ni-based anode electrode by 0.3 V to 0.4 V. In the negative voltage outputting rectifier circuit, particularly, the diodes are connected in series. Therefore, the threshold voltage is remarkably reduced and the voltage amplitude is increased by five times. As described above, the output voltage amplitude is improved in such a manner that the anode electrode of each diode in signal receiver 102 is made of a metal having a low work function.

As can be seen from the results in Table 2, only the anode electrode of each negative voltage outputting diode 110 in signal receiver 102 may be made of a metal having a low work function (e.g., Ti). Thus, the negative voltage output is considerably improved.

### FIRST MODIFICATION EXAMPLE

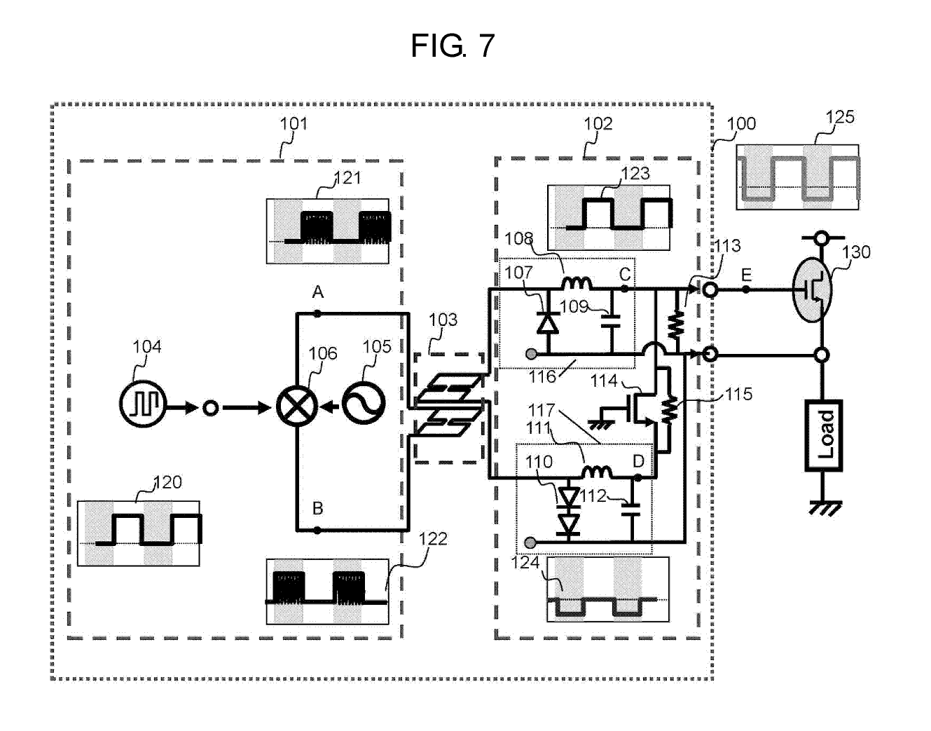

FIG. 7 illustrates a modification example of the gate drive apparatus according to the exemplary embodiment of the present disclosure. In FIG. 7, constituent elements similar to those illustrated in FIG. 1 are denoted with the same reference numerals. Gate drive apparatus 100 illustrated in FIG. 7 has a configuration that a switch including transistor 114 and resistor 115 switches between positive voltage outputting rectifier circuit 116 and negative voltage outputting rectifier circuit 117 in signal receiver 102. This configuration also produces advantageous effects similar to those described in the foregoing exemplary embodiment. As described above, the output voltage characteristic is improved in such a manner that the anode electrode of each rectifier circuit is made of a metal having a low work function.

In FIG. 7, transistor 114 has a gate input which is grounded (GND). Alternatively, transistor 114 may be directly controlled using an external signal.

### SECOND MODIFICATION EXAMPLE

The diode of oscillator circuit 105 adjusts the oscillation frequency by varying the capacitance. Therefore, the diode of oscillator circuit 105 may have a recess which does not pass through barrier layer 4. Alternatively, the diode of oscillator circuit 105 may have no recess.

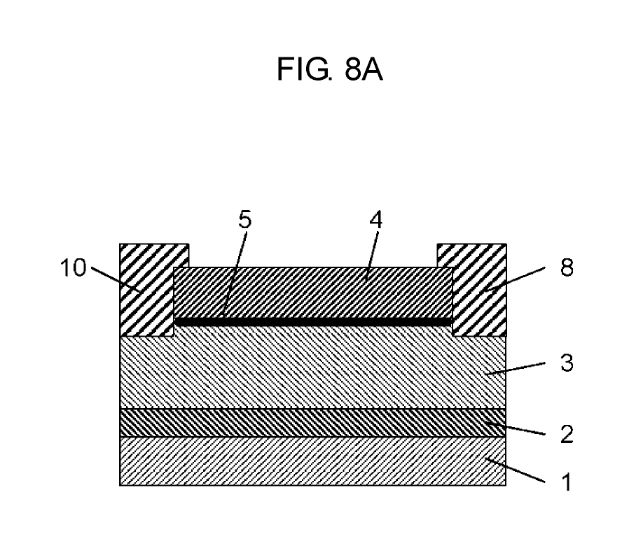

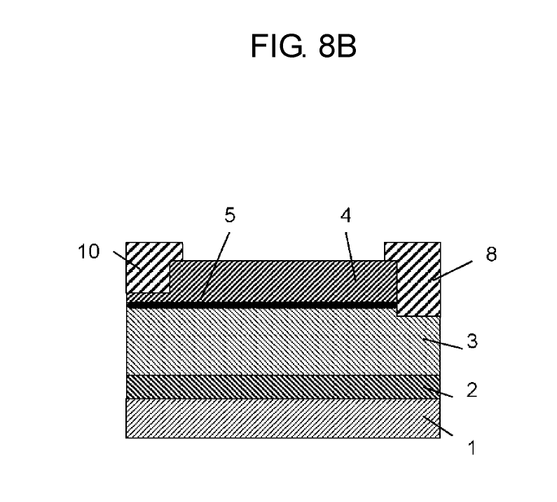

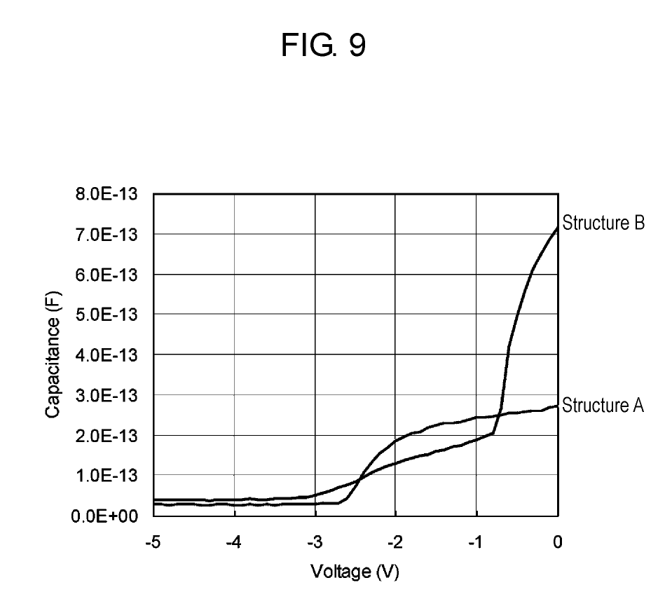

A second modification example of the gate drive apparatus according to the exemplary embodiment of the present disclosure relates to a structure of the diode in the gate drive apparatus. Description will be given of structures and a characteristic of the diode with reference to FIGS. 8A, 8B, and 9.

FIG. 8A illustrates the diode having a recess formed by removing barrier layer 4 so as to reach carrier supply layer 3 (structure A). FIG. 8B illustrates the diode in which barrier layer 4 is etched to a degree that carrier supply layer 3 is not exposed from barrier layer 4 (structure B). FIG. 9 illustrates results of measurement on a capacitance with regard to the diodes illustrated in FIGS. 8A and 8B. In FIG. 9, “E” on the vertical axis represents a power of 10. For example, “1.0E-13” represents 1.0×10⁻¹³. As illustrated in FIG. 9, the capacitance of the diode having structure A is considerably reduced since 2 DEG is not formed immediately below the anode electrode under a bias condition of 0 V. For this reason, the diode having structure A is suitable for the rectifier circuit. On the other hand, the capacitance of the diode having structure B is increased since 2 DEG is formed immediately below the anode electrode under the bias condition of 0 V. For this reason, the diode having structure B is suitable for the variable capacitance diode of the oscillator circuit 105.

### Implementable Examples of Layer Structure

In the foregoing exemplary embodiment, substrate 1 may be a GaN substrate, a sapphire substrate, or a spinel substrate in addition to the Si substrate. Moreover, the surface orientation of substrate 1 is not limited to the (111) plane, but may be a (001) plane. In the case of using a hexagonal crystal substrate such as the GaN substrate or the sapphire substrate, a c-plane ((0001) plane) is mainly used; however, an m-plane or an r-plane may also be used.

The thickness of buffer layer 2 is preferably 0.5 μm to 5 μm, and the thickness of carrier supply layer 3 is preferably 0.5 μm to 3 μm. The thickness of barrier layer 4 preferably falls within a range of 1 nm to 80 nm. Herein, a range described using “to” includes the both numeric values. For example, the range of 1 nm to 80 nm denotes a range between 1 nm and 80 nm (inclusive).

The compositions of buffer layer 2, carrier supply layer 3, and barrier layer 4 are not limited to those described above. For example, buffer layer 2 may be made of GaN, AlₓGa₁₋ₓN (0<x<1), or AlₓGa_{1-x-y}In_{y}N (0≦x≦1, 0≦y≦1) in addition to AlN. Moreover, carrier supply layer 3 may be made of AlₓGa₁₋ₓN (0<x≦1) or AlₓGa_{1-x-y}In_{y}N (0≦x≦1, 0≦y≦1) in addition to GaN.

### Implementable Examples of Electrode Structure

The structures of source electrode 6, drain electrode 7, and cathode electrode 8 are not limited to the multilayer structure of Ti and Al. Source electrode 6, drain electrode 7, and cathode electrode 8 may have a multilayer structure of other metals such as Hf, W, V, Mo, Au, Ni, and Nb.

The structure of gate electrode 9 is not limited to the multilayer structure of Ni and Au. Desirably, gate electrode 9 has a multilayer structure of metals having a work function so as to achieve a high Schottky barrier formed by a semiconductor and a metal. Also desirably, one of Ni, Pd, Au, Pt, and Ir is in contact with a semiconductor.

The structure of anode electrode 10 is not limited to the multilayer structure of Ti and Au. Desirably, anode electrode 10 has a multilayer structure of metals having a low work function. Also desirably, one of Ta, Ag, Al, Nb, V, Cr, W, and Mo is in contact with a semiconductor.

Table 3 shows a work function of a metal for the electrodes.

TABLE 3

| Metal | Work function (eV) |
|---|---|
| Ni | 5.15 |
| Pd | 5.12 |
| Au | 5.1 |
| Pt | 5.65 |
| Ir | 5.27 |
| Ti | 4.33 |
| Ta | 4.25 |
| Ag | 4.26 |
| Al | 4.28 |
| Nb | 4.3 |
| V | 4.3 |
| Cr | 4.5 |
| W | 4.55 |
| Mo | 4.6 |
| Hf | 3.9 |
| Nb | 4.3 |

As can been seen from Table 3, desirably, a metal having a work function of not less than 5 eV is used as the metal having the high work function, and a metal having a work function of less than 5 eV is used as the metal having the low work function.

The gate controllability of the transistor may be improved in such a manner that barrier layer 4 is partly etched to form a recess and gate electrode 9 is formed to cover the recess in a part of the gate region. The recess in the diode does not necessarily pass through barrier layer 4. Alternatively, the diode does not necessarily have a recess. However, the configuration according to the exemplary embodiment of the present disclosure allows the reduction in on resistance and capacitance.

### Other Implementable Example of Signal Receiver

In the foregoing exemplary embodiment, signal receiver 102 has the path to output the positive voltage and the path to output the negative voltage. Alternatively, signal receiver 102 may be configured to output only the positive voltage.

### Other Implementable Examples

The anode electrode of the variable capacitance diode for adjusting the frequency of the oscillator may be made of a metal having a high work function rather than Ti having a low work function. Moreover, the diode does not necessarily have the recess, but may have a recess formed by etching so as not to pass through the barrier layer.

The foregoing exemplary embodiment concerns the process of forming the transistor and diode. In practice, a capacitor and a spiral inductor may be formed using a protective film and a wire.

The transmission side or reception side of the electromagnetic resonance coupler may be mounted on the circuit board where signal transmitter (primary side) 101 or signal receiver (secondary side) 102 is mounted.

Oscillator circuit 105 and mixer circuit 106 of signal transmitter 101 may be mounted on the circuit board where the transmission side of electromagnetic resonance coupler 103 is mounted. Moreover, signal receiver 102 may be fabricated as a single circuit board. Furthermore, the reception side of electromagnetic resonance coupler 103 may be fabricated using a substrate with low dielectric loss, such as a ceramic substrate or a sapphire substrate. In other words, the gate drive apparatus may be configured with different chips. Alternatively, oscillator circuit 105 and mixer circuit 106 of signal transmitter 101, the transmission side of electromagnetic resonance coupler 103, and signal receiver 102 may be fabricated as an integrated circuit board. Moreover, the reception side of electromagnetic resonance coupler 103 may be fabricated using a substrate with low dielectric loss, such as a ceramic substrate or a sapphire substrate.

The foregoing description mainly concerns the GaN-based device structure; however, it can be considered that a GaAs- or Si-based device also produces similar advantageous effects to those of the GaN-based device described above in such a manner that the anode electrode of each diode in signal receiver 102 is made of a metal having a low work function.

A gate drive apparatus according to an exemplary embodiment of the present disclosure is useful as a gate drive apparatus for use in consumer products and on-vehicle power supply circuits.

What is claimed is:

1. A gate drive apparatus comprising:
a transmitter;
a receiver; and
a coupler disposed between the transmitter and the receiver,
wherein
the transmitter includes an oscillator having a diode,
the receiver includes a rectifier circuit having a diode, and
the diode of the transmitter is different in anode electrode from the diode of the receiver.

2. The gate drive apparatus according to claim 1, wherein the anode electrode of the diode in the transmitter is higher in work function than the anode electrode of the diode in the receiver.

3. The gate drive apparatus according to claim 1, wherein the rectifier circuit includes a first rectifier circuit configured to output a positive voltage, and a second rectifier circuit configured to output a negative voltage.

4. The gate drive apparatus according to claim 1, wherein
the transmitter further includes a gate control signal generator, and a mixer,
the oscillator generates a carrier signal,
the gate control signal generator generates a gate control signal, and
the mixer superimposes the carrier signal on the gate control signal to generate a superimposed signal, and generates a positive voltage output signal and a negative voltage output signal.

5. The gate drive apparatus according to claim 1, wherein
each of the diodes includes:
a substrate;
a buffer layer, a carrier supply layer, and a barrier layer sequentially disposed on the substrate and each made of a group III nitride semiconductor; and
a cathode electrode and an anode electrode disposed on the carrier supply layer or the barrier layer.

6. The gate drive apparatus according to claim 5, wherein the diode of the rectifier circuit has, as a part of the anode electrode, a recess formed to pass through the barrier layer and reach the carrier supply layer.

7. The gate drive apparatus according to claim 5, wherein
the oscillator includes a transistor, and
the transistor includes
a substrate,
a semiconductor layer including a buffer layer, a carrier supply layer, and a barrier layer each made of a nitride semiconductor, the semiconductor layer being disposed on the substrate, and
a source electrode, a drain electrode, and a gate electrode disposed on the semiconductor layer.

8. A gate drive apparatus comprising:
a transmitter;
a receiver; and
a coupler disposed between the transmitter and the receiver,
wherein
the receiver includes a first rectifier circuit having a first diode, and a second rectifier circuit having a second diode, and
the first diode is different in anode electrode from the second diode.

9. The gate drive apparatus according to claim 8, wherein
the first rectifier circuit is configured to output a positive voltage and the second rectifier circuit is configured to output a negative voltage.

10. The gate drive apparatus according to claim 8, wherein
the anode electrode of the first diode is higher in work function than the anode electrode of the second diode.

11. The gate drive apparatus according to claim 8, wherein
the transmitter includes an oscillator, a gate control signal generator, and a mixer,
the oscillator generates a carrier signal,
the gate control signal generator generates a gate control signal, and
the mixer superimposes the carrier signal on the gate control signal to generate a superimposed signal, and generates a positive voltage output signal and a negative voltage output signal.

12. The gate drive apparatus according to claim 8, wherein
each of the diodes includes:
a substrate;
a buffer layer, a carrier supply layer, and a barrier layer sequentially disposed on the substrate and each made of a group III nitride semiconductor; and
a cathode electrode and an anode electrode disposed on the carrier supply layer or the barrier layer.

13. The gate drive apparatus according to claim 12, wherein the diode of the rectifier circuit has, as a part of the anode electrode, a recess formed to pass through the barrier layer and reach the carrier supply layer.

14. The gate drive apparatus according to claim 12, wherein
the oscillator includes a transistor, and
the transistor includes
a substrate,
a semiconductor layer including a buffer layer, a carrier supply layer, and a barrier layer each made of a nitride semiconductor, the semiconductor layer being disposed on the substrate, and
a source electrode, a drain electrode, and a gate electrode disposed on the semiconductor layer.
